(19) United States
(12) Patent Application Publication
(10) Pub. No.: US 2004/0175961 A1
(43) Pub. Date: Sep. 9, 2004

(54) Two-step post nitridation annealing for lower EOT plasma nitrided gate dielectrics

(76) Inventor: Christopher Olsen, Fremont, CA (US)

Correspondence Address: PATENT COUNSEL, APPLIED MATERIALS, INC., LEGAL AFFAIRS DEPT., P.O. BOX 450A, Santa Clara, CA, 95052, US

(21) Appl. No.: 10/794,707

(22) Filed: Mar. 4, 2004

Related U.S. Application Data
(60) Provisional application No. 60/453,057, filed on Mar. 7, 2003.

(51) Int. Cl. H01L 21/3205

(52) U.S. Cl. 438/786

(57) ABSTRACT

A method of forming a dielectric film that includes nitrogen. The method includes incorporating nitrogen into a dielectric film using a plasma nitridation process to form a silicon oxynitride film. The silicon oxynitride film is annealed first in an inert or reducing ambient at a temperature ranging between about 700° C. and 1100° C. The silicon oxynitride film is annealed for the second time in an oxidizing ambient at a temperature ranging between about 900° C. and 1100° C.

### RELATED APPLICATIONS

This application is related to and claims the benefit of U.S. Provisional Patent application serial No. 60/453,057 filed Mar. 7, 2003, which is hereby incorporated by reference in its entirety.

### BACKGROUND

1). Field

The present invention relates generally to the field of semiconductor manufacturing. More specifically, the present invention relates to a method of forming a silicon oxynitride (SiON or SiOₓN_{y}) gate dielectric and integrating it into a gate stack using a plasma nitridation and two-stop post plasma nitridation annealing processes.

2). Description of the Related Art

Integrated circuits are made up of literally million of active and passive devices such as transistors, capacitors and resistors. A transistor 100 generally includes a source 102, a drain 104, and a gate stack 106. The gate stack (FIG. 1) consists of a substrate 108 (e.g., typically made of silicon) on top of which is grown a dielectric 110 (typically made of silicon dioxide (SiO₂)) and this is capped with an electrode 112 (made with a conductive material such as polycrystalline silicon).

In order to provide more computational power, the trend is to scale down transistors by shrinking device geometry. Moore's law scaling requires that the gate drive current must increase in order to increase the speed of the transistor. The gate drive current give by equation (1) can be increased by increasing the gate capacitance (Cₒₓ), which in turn (as shown by equation (2)) can be increased by either decreasing the dielectric thickness (d) or using a dielectric that has higher dielectric constant (k) than the existing SiO₂ dielectric (k=3.9).

$$\begin{matrix}{I}_{D} ∼ μ \text{/} Lg * {{C}_{ox} ( {V}_{DD} - {V}_{TH} )}^{2} & ( 1 ) \\ {C}_{ox} = \frac{kA}{d} & ( 2 )\end{matrix}$$

where I_{D} is the Drive Current; μ is the Carrier Mobility, Lg is the gate length, COX is the Gate Capacitance, V_{DD} is the Opening Voltage; V_{TH} is the Threshold Voltage; k is the dielectric constant, d is the dielectric thickness, and A is the device area.

To avoid complex integration and materials handling issues, device manufacturers would like to scale the device parameters as much as they can by decreasing the dielectric thickness. However lowering the SiO₂ thickness below 20 Å results in poor gate reliability due to increase in tunneling current, increase in boron penetration into the substrate and poor process control for very thin oxide. While in theory the alternative of using a higher k gate dielectric appears very attractive, the material compatibility with the underlying Si substrate and the polysilicon gate electrode cannot be matched to what is provided with SiO₂. Additionally, using SiO₂ eliminates many materials handling contamination issues that must be dealt with when introducing rare-earth oxide as gate dielectrics.

Challenges encountered in extending SiO₂ to 0.1 μm technology node and beyond, include: (1) boron penetration in a transistor such as a PMOS device with a P+ boron (B) doped gate electrode into the gate oxide and underlying Si substrate, (2) increasing gate leakage current with decreasing gate oxide thickness, and (3) reliability of the thin dielectric, hot carrier degradation for NMOS (Negative Channel Metal Oxide Semiconductor) and Negative Bias Temperature Instability (NBTI) for PMOS (Positive Channel Metal Oxide Semiconductor).

Nitridation of the SiO₂ layer to form silicon oxynitride (SiOₓN_{y} or alternatively SiON) has evolved as a promising candidate to scale the SiO₂ dielectric down to 0.1 μm device generations. Incorporating nitrogen into the dielectric film blocks boron as well as increases the dielectric constant of the gate dielectric. The increase in the dielectric constant means a thicker dielectric can be used in comparison to pure SiO₂ hence reducing gate leakage. For the nitrogen (N) doping to be effective in circumventing the challenges described above in ultra-thin (e.g., 12 Å) gate dielectrics, it is essential to have high (about equal to or greater than 5%) total concentration of nitrogen in the dielectric film with the peak of the nitrogen concentration profile at the top surface of the gate dielectric, which leads to improved drive current and NBTI reliability.

Thermally grown silicon oxynitride has been used as gate dielectrics for several years from the 0.2 μm to 0.13 μm device generations. As the device technology has advanced from 0.2 μm to 0.1 μm the gate oxide has thinned from >25 Å to <12 Å. Hence, in order to block boron and reduce gate leakage the amount of nitrogen in the film has to be increased from <3% to 5-10%. When nitric oxide (NO) and nitrous dioxide (N₂O) are used to grow the oxynitride gate dielectric the Nitrogen gets incorporated in the dielectric film simultaneously as the oxynitride grows, hence nitrogen is distributed evenly in the film. If NO or N₂O are used to form silicon oxynitride by annealing an existing SiO₂ layer at elevated temperatures, the nitrogen incorporated by growing SiON at the Si-substrate/Oxide interface. Hence, nitrogen is incorporated at this interface. The amount of nitrogen in the later case (<2%) is less than in the former case (4-5%).

More recently, plasma nitridation has been used to nitride (to incorporate nitrogen into) the gate oxide. This technique results in high nitrogen concentration at the poly gate/oxide interface, which prevents boron penetration into the oxide dielectric. At the same time, the bulk of the oxide dielectric gets lightly doped with unassociated nitrogen during the plasma nitridation process, which reduces the electrical oxide thickness (EOT) over the starting oxide. This allows one to achieve a gate leakage reduction at the same EOT higher than conventional thermal processes. Scaling this dielectric in the EOT <12 Å range while preserving good channel mobility and drive current (Idsat) has been the industry challenge.

Post-annealing the silicon oxynitride after the plasma nitridation at high temperature has shown to improve the peak transconductance, gm, as a proxy for channel mobility, at the expense of the EOT increasing, FIG. 2. In FIG. 2, the x-axis represents the EOT thickness and the y-axis represents gm degradation. For an example, an SiO₂ film of about 6 Å is used as the base oxide. After plasma nitridation, various post-annealing conditions are used to anneal the film. For instance, a 1000° C. annealing for 30 seconds at 740 Torr in the presence of nitrogen gas is used in one case. In another instance, a 1050° C. annealing for 1 second at 0.5 Torr is used. In another instance, a 1000° C. annealing for 15 seconds at 3 Torr in the presence of nitrogen and oxygen gas is used. In another instance, a 1100° C. annealing for 15 seconds at 0.5 Torr, or a 1050° C. annealing for 1 second at 15 Torr is used. In yet another instance, a 950° C. annealing for 1 second at 15 Torr is used. As shown in this figure, channel mobility is degraded more at the lower EOT thickness and degraded less at the higher EOT thickness. This indicates that as channel mobility increases, the EOT thickness increases. In addition, thicker EOT also decreases Idsat, which is undesirable.

The prior art thus lacks of the ability to make a silicon oxynitride film that has thinner EOTs with improved mobility.

### SUMMARY

The exemplary embodiments of the present invention pertain to a method of forming a silicon oxynitride film with improved channel mobility and with a thinner EOT by a two-step annealing of the plasma treated gate dielectric, which entails first using an inert or reducing ambient and followed by an oxidizing ambient in a post nitridation anneal (PNA) process.

According to an aspect of the invention, a method of forming a dielectric film includes incorporating nitrogen into a dielectric film using a plasma nitridation process. A silicon oxynitride film is formed as a result of the plasma nitridation. The silicon oxynitride film is subjected to a two-step PNA process in which the silicon oxynitride film is first annealed in the presence of an inert or reducing ambient (e.g., using nitrogen or hydrogen gas). Following the first anneal, the silicon oxynitride is annealed the second time in an oxidizing ambient (e.g., using oxygen gas).

According to another aspect of the invention, a method of forming a gate stack includes forming a silicon dioxide film on a substrate. A silicon oxynitride film is formed by incorporating nitrogen into the silicon dioxide film using plasma nitridation. The silicon oxynitride film is subjected to a two-step PNA process in which the silicon oxynitride film is first annealed in the presence of an inert or reducing ambient (e.g., using nitrogen or hydrogen gas). Following the first anneal, the silicon oxynitride is annealed the second time in an oxidizing ambient (e.g., using oxygen gas). A cap layer is formed on the silicon oxynitride.

### BRIEF DESCRIPTION OF THE DRAWINGS

Embodiments of the present invention is illustrated by way of examples and not limitations in the figures of the accompanying drawings, in which like references indicate similar elements and in which:

FIG. 1 illustrates an exemplary gate stack transistor;

FIG. 2 illustrates how high temperature post annealing after plasma nitridation improves peak transconductance;

FIG. 3 illustrates the effects of a two-step post plasma nitridation annealing on the EOT of a silicon oxynitride film formed by plasma nitridation;

FIG. 4 illustrates the effects of a two-step post plasma nitridation annealing on the Drive Current Idsat and the EOT of a silicon oxynitride film formed by plasma nitridation;

FIG. 5 illustrates cluster tool that can be used for some of the embodiments of the present invention; and

FIG. 6 illustrates an exemplary sequence of forming a gate stack in accordance to embodiments of the present invention.

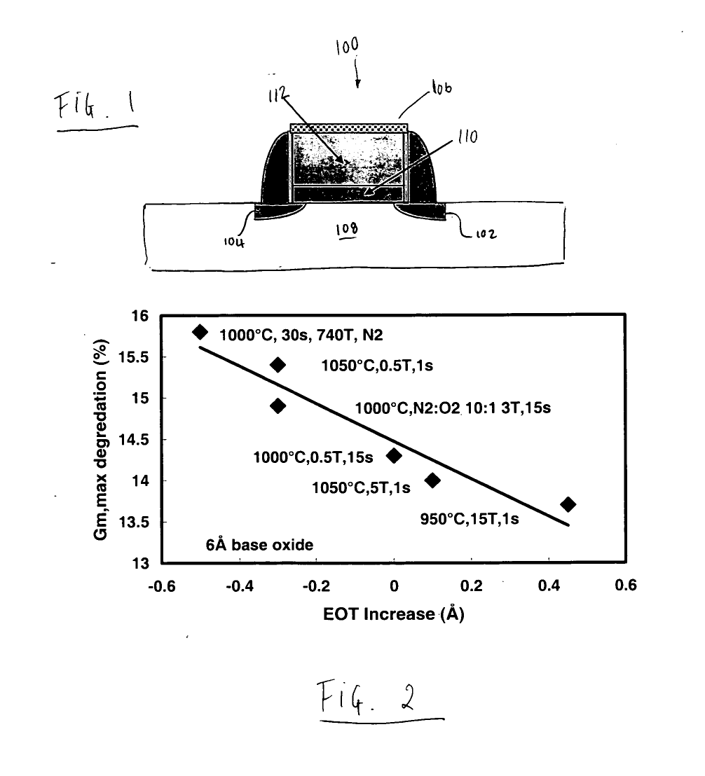

### DETAILED DESCRIPTION

Embodiments of the present invention include a novel method of forming a dielectric film that includes nitrogen, such as SiON or SiOₓN_{y} (silicon oxynitride) using a nitrogen plasma (or plasma nitridation) process. The silicon oxynitride is subjected to two post plasma nitridation annealing processes. The embodiments allow for the control of the EOT and the nitrogen concentration profile of the silicon oxynitride film.

In the following description, for purposes of explanation, numerous specific details are set forth in order to provide a thorough understanding of the present invention. It will be evident, however, to one skilled in the art that the present invention may be practiced without these specific details. In other instances, specific apparatus structures and methods have not been described so as not to obscure the present invention. The following description and drawings are illustrative of the invention and are not to be construed as limiting the invention.

In one embodiment, there is provided a method of forming a silicon oxynitride dielectric film using a plasma nitridation process such as Decoupled Plasma Nitridation (DPN). After the plasma nitridation, the silicon oxynitride film is subjected to two post plasma nitridation annealing (PNA) processes. A first PNA process is done using an inert agent or a reducing agent to densify the silicon oxynitride. The two PNA processes also move nitrogen towards the surface of the silicon oxynitride film and the oxygen toward the interface of the silicon oxynitride and the substrate. Thus Boron can be blocked more efficiently. In addition, the concentration profile of nitrogen tends to peak at the surface of the silicon oxynitride. A second PNA process is done using an oxidizing agent to modify the nitrogen concentration profile.

In another embodiment, there is provided a method of integrating the silicon oxynitride film formed using a plasma nitridation process and a two-step PNA process into a gate stack for forming a semiconductor device such as a transistor.

In one embodiment, a substrate having a silicon dioxide (SiO₂) film formed thereon is subjected to a plasma nitridation process to convert the silicon dioxide film into a silicon oxynitride film. In one embodiment, the plasma nitridation process used is Decoupled Plasma Nitridation (DPN), which is known in the art. DPN is a technology using inductive coupling to generate nitrogen plasma and incorporate a high level of nitrogen onto an oxide film. In DPN, a surface of a film, e.g., an SiO₂ film, is bombarded with nitrogen ions which break the SiO₂ film and bond the nitrogen ions to the SiO₂ film forming a silicon oxynitride film. In one embodiment, nitrogen gas is used to provide the nitrogen source. The SiO₂ film is thus exposed to decoupled nitrogen plasma. In one embodiment, DPN is performed in a chamber with pressure ranging from about 5-20 mTorr or 10-20 mTorr, with a plasma power of about 200-800 Watt. The nitrogen gas may be flown into the chamber at a flow rate ranging from about 100-200 sccm. In one embodiment, the DPN uses a pulse radio frequency plasma process at about 10-20 mHz and pulse at about 5-15 kHz. The DPN process parameters can be modified depending on the chamber size and volume and the thickness of the dielectric film.

In one embodiment, the nitrogen plasma treated film, the silicon oxynitride film is annealed twice. In the first annealing process, the silicon oxynitride is annealed to densify the nitrogen. The first annealing process is carried out in an inert ambient, using an inert gas such as N₂, He, Ar, or the combination thereof. Alternatively, the annealing process is carried out in a reducing ambient, using an inert gas or a mixture of inert gases such as H₂, H₂/N₂, H₂/Ar, or H₂/He. In one embodiment, the first annealing process is carried out immediately after the plasma nitridation process. In one embodiment, the first PNA process is carried out at a temperature >700° C. for 1-120 seconds at a pressure ranging from about 100 mTorr to about 800 Torr. The second PNA process follows the first PNA process. In one embodiment, after the first PNA process, the annealing ambient is changed over to one which contains an oxidizer agent (or an oxygen comprising agent) such as O₂, O₂/N₂, O₂/Ar, O₂/He, N₂O, or NO. The second PNA process is carried out at a reduced pressure ranging from about 10 mTorr to about 100 Torr and at a temperature between about 900° C. and about 1100° C. or between about 1000° C. and 1050° C. The second PNA process can be carried out for about 1-120 seconds. In one embodiment, the temperature, time, and partial pressure of the second PNA process are controlled to achieve a 0.1 Å to 2 Å increase in the EOT of the silicon oxynitride.

In one embodiment, both of the first PNA process and the second PNA process are performed in a single wafer rapid thermal processing (RTP) chamber configured to carry out the rapid thermal annealing (RTA) process. A commercially available reduced pressure RTP chamber hardware such as XE, XE Plus or Radiance made by Applied Materials, Inc. can be used to carry out the first and second PNA processes.

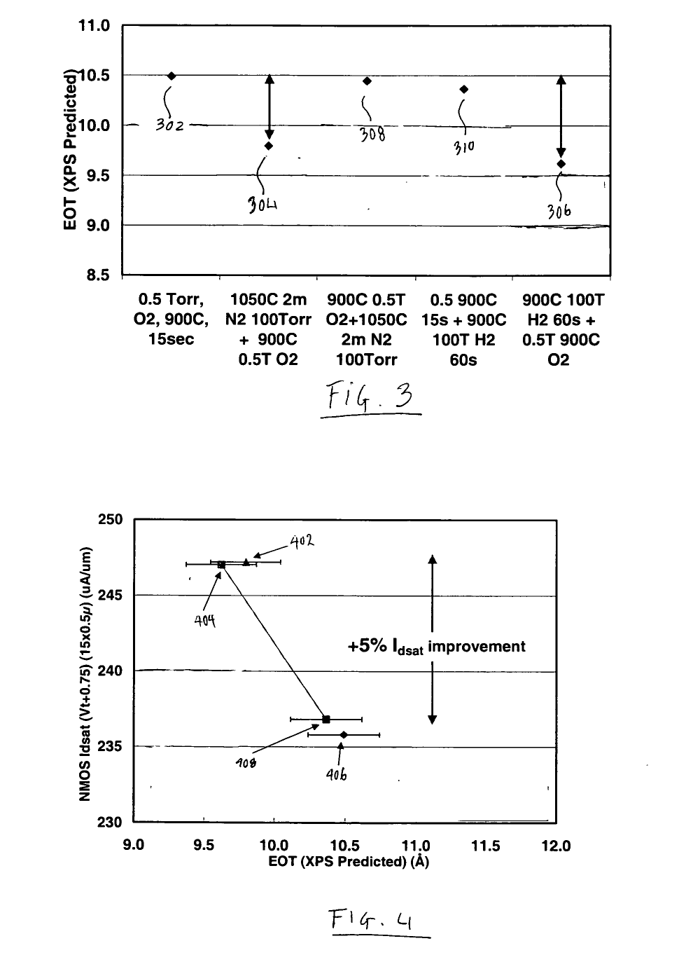

In FIG. 3, it is shown that annealing the silicon oxynitride film formed using plasma nitridation in an inert or reducing environment followed by annealing in an oxidizing environment allows for the silicon oxynitride film to have an EOT that is 0.7-0.9 Å thinner which is approximately a 10% improvement. Such a reduction in EOT is a significant ˜10% improvement in the 10 Å EOT range.

In one embodiment, an 8 Å thick silicon dioxide is used as a base film for the silicon oxynitride to be formed using plasma nitridation. The plasma nitridation using about 7% nitrogen is used to convert the silicon dioxide film into a silicon oxynitride film. The plasma nitridation process is carried out at a pressure of about 10 mTorr using radio frequency inductive plasma. The silicon oxynitride film is then treated with various PNA annealing processes.

As shown in FIG. 3, point 302 illustrates the EOT result of the silicon oxynitride film being treated with a PNA annealing process using an oxidizing ambient using oxygen. In one embodiment, the silicon oxynitride film at point 302 is annealed at 0.5 Torr and 900° C. for about 15 seconds in the presence of O₂ gas. The EOT of the silicon oxynitride film at point 302 is about 10.5 Å.

Point 304 illustrates the EOT result of the silicon oxynitride film being treated with a two-step PNA annealing process (as previously described) in which the EOT of the silicon oxynitride film is about 9.75 Å. There is a decrease of about 0.75 EOT A between the silicon oxynitride at point 302 and at point 304. At point 304, after the plasma nitridation process, the silicon oxynitride film is first annealed in a reducing or inert ambient using N₂ gas followed by a second anneal in an oxidizing ambient using O₂ gas. In one embodiment, the silicon oxynitride film at point 304 is annealed first with N₂ gas at 1050° C. and 100 Torr for about 2 minutes followed by a second anneal with O₂ gas at 900° C. and 0.5 Torr for about 15-60 seconds.

Point 306 illustrates the EOT result of the silicon oxynitride film being treated with a two-step PNA annealing process (as previously described) in which the EOT of the silicon oxynitride film is about 9.55 Å. There is a decrease of about 1.0 EOT A between the silicon oxynitride at point 302 and at point 306. At point 306, after the plasma nitridation process, the silicon oxynitride film is first annealed in a reducing or inert ambient using H₂ gas followed by a second anneal in an oxidizing ambient using O₂ gas. In one embodiment, the silicon oxynitride film at point 306 is annealed first with H₂ gas at 900° C. and 100 Torr for about 1 minutes followed by a second anneal with O₂ gas at 900° C. and 0.5 Torr for about 15-60 seconds.

The results in FIG. 3 illustrate that the two-step PNA, first with a reducing or inert ambient and second with an oxidizing ambient, significantly decreases the EOT for the silicon oxynitride film (by about 10%). The results also illustrate that annealing first with an oxidizing agent followed by a second annealing using a reducing or inert agent does not provide the same effect. For example, as shown at point 308, the silicon oxynitride is annealed first in O₂ gas then annealed again in the N₂ gas. The silicon oxynitride film at point 308 has an EOT value of about 10.4 Å, essentially, no change from the silicon oxynitride film at point 302. Additionally, as shown at point 310, the silicon oxynitride is annealed first in O₂ gas then annealed again in the H₂ gas. The silicon oxynitride film at point 310 has an EOT value of about 10.4 Å, essentially, no change from the silicon oxynitride film at point 302. Annealing the silicon oxynitride film after the plasma nitridation process first in a reducing or inert ambient (e.g., N₂ or H₂ gas) results in densification of the silicon oxynitride film before oxidation (by the second annealing in an oxidizing ambient using, for example, O₂). The densification of the silicon oxynitride results in at least about 0.7-0.9 Å thinner EOT.

In FIG. 4, it is shown that the annealing the silicon oxynitride film first in a reducing or inert ambient using, for example, H₂ or N₂ gas before the annealing the silicon oxynitride film in an oxidizing ambient, for example, O₂ gas showed both a thinner EOT film in addition to a 5% improvement in saturation drive current Idsat. The Idsat improvement is significantly larger for a ˜0.5-0.7 Å thinner EOT, compared to the conventional +2 to +3% Idsat improvement per EOT A conventionally observed in CMOS scaling.

As shown in FIG. 4, at point 402, the silicon oxynitride film is first annealed using N₂ gas at 1050° C. then annealed again with O₂ gas at 900° C. The silicon oxynitride at point 402 has an NMOS Idsat of about 247.5 μA/μm. Similarly, at point 404, the silicon oxynitride film is first annealed using H₂ gas at 900° C. then annealed again with O₂ gas at 900° C. The silicon oxynitride at point 404 also has an NMOS Idsat of about 247.5 μA/μm. Thus, annealing the silicon oxynitride film (after plasma nitridation) first with a reducing or inert gas such as N₂ or H₂ followed by annealing with an oxidizing gas such as O₂ results in a silicon oxynitride film with high Idsat. As shown in FIG. 4, at point 406, the silicon oxynitride film is only annealed using O₂ gas at 900° C. The silicon oxynitride at point 406 has an NMOS Idsat of only about 235.5 μA/μm. And, at point 408, the silicon oxynitride film is annealed first with O₂ gas at 900° C. followed by a second anneal with H₂ gas at 900° C. The silicon oxynitride at point 408 has an NMOS Idsat of only about 236 μA/μm. As can be seen, the two-step post nitridation annealing, first in a reducing or inert ambient and second in an oxidizing ambient produces a silicon oxynitride film with a significantly increased Idsat (about 5% improvement).

Also in FIG. 4, it is shown that the two-step post nitridation annealing, first in a reducing or inert ambient and second in an oxidizing ambient produces a silicon oxynitride film with a significantly decreased EOT as previously discussed.

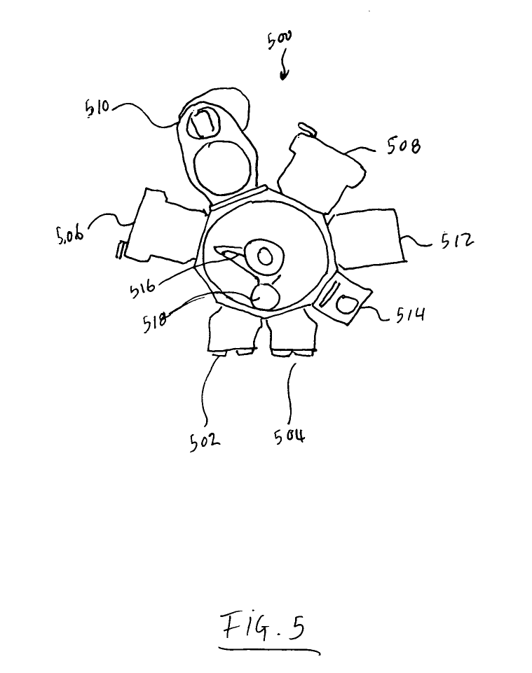

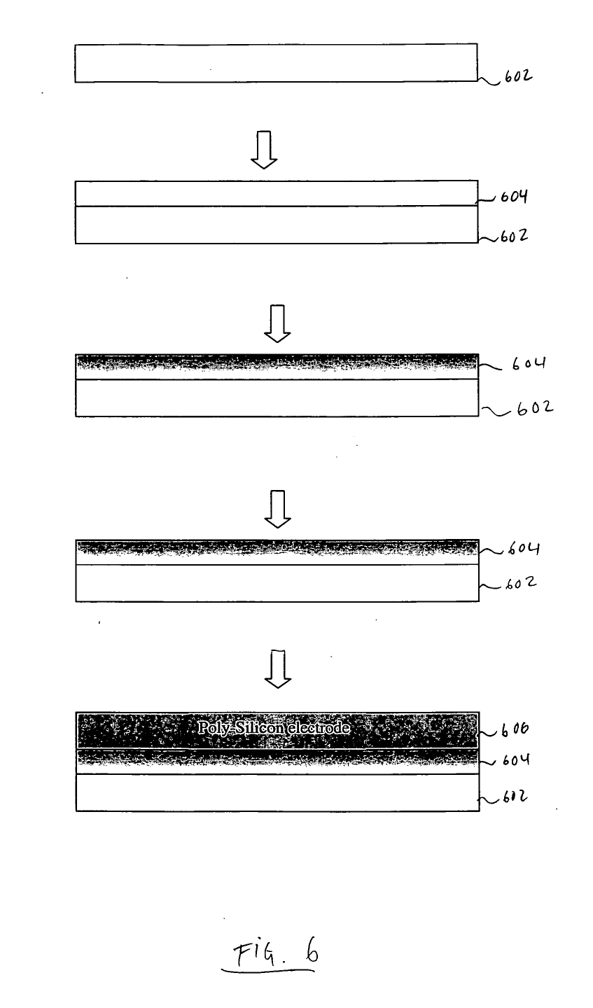

In one embodiment, a gate stack is formed incorporating the methods of forming the silicon oxynitride previously described. The gate stack can be formed in a cluster tool such as an integrated Gate Stack Centura made by Applied Materials, Inc. An example of cluster tool is shown in FIG. 5. In such embodiment, the entire gate stack from the gate oxide formation, N doping of the silicon oxynitride dielectric, thermal stabilization of the N doped film, and gate electrode formation is manufactured within as single tool with multiple chambers without breaking vacuum. Advance technology nodes (about equal to or less than 1 μm) will have a few monolayers of oxide film 6-14 Å as gate dielectric. Processing the gate stack within a single tool with controlled ambient without vacuum break and human handling/interference will eliminate any compromise to the device integrity as a result of contamination or damage from exposure to the fabrication ambient and handling of the wafer multiple times.

FIG. 5 illustrates a cluster tool 500, which comprises several processing chambers, e.g., loadlock chambers 502 and 504, RTP chambers 506 and 508, a DPN chamber 510, a deposition chamber 512 (e.g., for depositing a polysilicon film), and a cool down chamber 514. The cluster tool 500 also includes a wafer-handling tool 516 used to transfer a substrate 518 (e.g., wafer) in and out of particular processing chamber. The wafer-handling tool 516 is typically located in a transfer chamber that can communicate to all of the processing chambers. The loadlock chambers 502 and 504 house substrates (e.g., wafers) to be processed. The deposition chamber 512 can be conventional chemical or physical vapor deposition that can be used to form a film or a layer as is known in the art. In one embodiment, the deposition chamber 512 is a deposition chamber that can be configured to form a polysilicon film or other electrode film. The chambers 506 and 508 are chambers that can be configured to run a rapid thermal annealing (RTA) process at a reduced or ultra-low pressure (e.g., about equal to or less than 10 Torr). The DPN chamber 510 can be a conventional plasma nitridation chamber that can be incorporated into the cluster tool 500.

With reference to FIG. 6, a sequence is described for forming an SiO₂ dielectric that is transformed into a silicon oxynitride dielectric. In one embodiment, the SiO₂ film 604 is thermally grown on a substrate 602. The substrate 602 can be a monocrystalline silicon or a semiconductor wafer typically used in making semiconductor devices. In one embodiment, the SiO₂ film 604 has a physical thickness of about 4-15 Å.

In one embodiment, the SiO₂ film 604 is grown using a reduced pressure RTP chamber such as the RTP chamber 506 of the cluster tool 500 (FIG. 5). The SiO₂ film 604 can be formed by a rapid thermal oxidation, which is an oxidation process where the chamber uses lamp(s) to quickly heat and dry a substrate surface to form an oxidized layer in the presence of oxygen. The rapid thermal oxidation of a silicon substrate (or a wafer) can be carried out using a dry process rapid thermal oxidation with the presence of O₂, O₂+N₂, O₂+Ar, N₂O, or N₂O+N₂ gas mixtures. The gas or gas mixtures can have a total flow rate of about 1-5 slm. Alternatively, the rapid thermal oxidation of a silicon substrate can be carried out using a wet process such as In-Situ Steam Generation (ISSG) with the presence of O₂+H₂, O₂+H₂+N₂, or N₂O+H₂ having, for example, a total flow rate of about 1-5 slm with 1-13% H₂. In one embodiment, the rapid thermal oxidation process to form the SiO₂ dielectric film is formed at a processing temperature of about 750-1000° C. and a processing pressure of about 0.5-50 Torr for about 5-90 seconds which results in a SiO₂ dielectric film having a thickness in the range of 4-15 Å.

In one embodiment, after the SiO₂ dielectric film 604 is formed in the RTP chamber 506, the substrate 602 is transferred to the DPN chamber 510 of the cluster tool 500 under an inert (e.g., N₂ or Ar) environment with the transfer chamber pressure being approximately at the same pressure for the plasma nitridation process (e.g., about 10 Torr). The plasma nitridation process exposes the SiO₂ film 604 to nitrogen plasma and incorporates nitrogen into the SiO₂ dielectric film 604 to form a silicon oxynitride film 606. In one embodiment, the DPN chamber 510 is a reduced pressure inductively coupled RF plasma reactor that can accommodate an inert gas such as N₂, He, or Ar.

The silicon oxynitride film 606 is then subjected to a two-step post nitridation anneal (PNA) process in an RTP chamber, e.g., the RTP chamber 508 of the cluster tool 500. The RTP chamber 508 can be a reduced pressure chamber reactor such as an Applied Material reactor XE, XE Plus, or Radiance. The PNA occurs, first in a non-oxidizing ambient (inert or reducing ambient) to densify the nitrogen plasma treated film (the silicon oxynitride film 606) at a temperature of about equal to or greater than 700° C., followed by a second anneal in an oxidizing ambient at a temperature of about equal to or greater than 900° C. For the first PNA process, an inert gas or a reducing gas (e.g., N₂ or H₂) can be flown into the RTP chamber to densify the silicon oxynitride film 606. In one embodiment, the first PNA includes heating up the substrate having the silicon oxynitride film 606 to the appropriate annealing temperature of about equal to or greater than 700° C. at less than or equal to about 5 Torr total pressure. In one embodiment, the inert gas or the reducing gas such as N₂ or H₂ gas of about 1 slm is flown into the RTP chamber for about 60-120 seconds. Following the first PNA, the RTP chamber is evacuated of the reducing or inert gas and an oxidizing gas such as O₂ is flown into the RTP chamber for the second PNA. The temperature may be reduced to about or greater than 900° C. The oxidizing gas can be flown into the RTP chamber at about 1 slm total flow rate for about 15 seconds. It is to be appreciated the flow rates mentioned are examples only for a particular reactor or processing chamber size (e.g., a 200 mm reactor). The flow rates are proportionately adjusted (increased or decreased) for other size reactors owing to the difference in volume.

In one embodiment, following the two-step PNA process, the silicon oxynitride film 606 is capped with a conductive layer such as a polysilicon film 606. The polysilicon film 606 can be formed in a deposition chamber such as the deposition chamber 512 of the cluster tool 500 (FIG. 5). Instead of polysilicon, the film 606 can be an amorphous silicon film or other suitable conductive film. The deposition chamber 512 can be a low-pressure chemical vapor deposition chamber (LPCVD) that can be incorporated into the cluster tool 500. After the formation of the polysilicon film 606, the gate stack can then be transferred to a cool down chamber such as the cool down chamber 514 and then be transferred to a storage area such as the loadlock 514 for further processing, testing, or other processes as known in the art.

It is to be appreciated that the gate stack that includes the gate dielectric film and the polysilicon cap film can be formed in several processing chambers not necessarily incorporated into the cluster tool 500 previously described. For instance, the SiO₂ dielectric film can be formed first in one chamber. The SiO₂ film can be converted into silicon oxynitride in a plasma nitridation chamber. The silicon oxynitride is then annealed in a two-step PNA process using an RTP chamber. And, the polysilicon film is formed over SiON or. SiOₓN_{y} film in the same RTP chamber.

A transistor formed with the gate stack as described herein has optimized performance due to the continuous and uniform processing envirorunent or ambient owing to the use of the cluster tool 500, in one embodiment. The processing of the gate stack is formed without a break between any of the processes. Thus, better scaling in terms of reduced Electrical Oxide Thickness, leakage, or Drive Current Idsat can be achieved as compared to processes with breaks in between various processes.

Without intending to be limited to any particular theory of invention, it is believed with nitrogen plasma treatment, the films are damaged with broken bonds which is inferred from a rise in the wet HF etch rate of the film compared to films of pure SiO₂. After post nitridation anneal in an inert atmosphere, the wet HF etch rate for the same film is lower than for SiO₂. If the same nitrided film is first post-annealed in O₂, the whole film may grow and react with the O₂ much faster due to the broken bonds in the film, not just at the SiOₓN_{y}/Si interface, where SiO₂ is known to grow. By first densifying the SiOₓN_{y} film in inert or reducing environment prior to anneal in an oxidizing atmosphere, the bonds are mended and further annealing in O₂ only occurs at the SiOₓN_{y}/Si interface where SiO₂ growth or interface repair is more important in improving Idsat, drive current. Additionally, by first densifying the SiOₓN_{y} film in the reducing environment, when the film is annealed in the oxidizing ambient, the nitrogen tends to get pushed more toward the top surface of the film. Thus, the nitrogen concentration profile tends to peak at the top surface.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A method of forming a dielectric film comprising:
incorporating nitrogen into a dielectric film using a plasma nitridation process to form a silicon oxynitride film;
annealing the silicon oxynitride film in an inert or reducing ambient at a temperature ranging between about 700° C. and 1100° C.; and
annealing the silicon oxynitride in an oxidizing ambient at a temperature ranging between about 900° C. and 1100° C.

2. The method of forming a dielectric film of claim 1 wherein the nitrogen incorporated into the dielectric film forms a nitrogen concentration peak that occurs at the top surface of the dielectric film.

3. The method of forming a dielectric film of claim 1 wherein the nitrogen incorporated into the dielectric film has a nitrogen concentration equal to or greater than 5%.

4. The method of forming a dielectric film of claim 1 wherein the dielectric film is equal to or less than about 14 angstrom.

5. The method of forming a dielectric film of claim 1 wherein the annealing of the silicon oxynitride film in an inert or reducing ambient includes annealing the silicon oxynitride film in an inert gas or a mixture of inert gas.

6. The method of claim 1 wherein the annealing of the silicon oxynitride film in an oxidizing ambient includes annealing the silicon oxynitride film with oxygen (02) or oxygen comprising gas.

7. The method of forming a dielectric film of claim 1 wherein the dielectric film is silicon dioxide (SiO₂).

8. The method of forming a dielectric film of claim 1 wherein the plasma nitridation process includes decoupled plasma nitridation.

9. A method of forming a gate stack comprising:
forming a silicon dioxide film on a substrate;
incorporating nitrogen into the silicon dioxide film using a plasma nitridation process to form a silicon oxynitride film, the plasma nitridation occurs at pressure less than about 10 mTorr in a presence of nitrogen gas;
annealing the silicon oxynitride film in an inert or reduced ambient at a temperature ranging between about 700° C. and 1100° C.;
annealing the silicon oxynitride film in an oxidizing ambient at a temperature between about 700° C. and 1100° C.; and
forming a cap layer on the silicon oxynitride.

10. The method of forming a gate stack of claim 9 wherein the annealing of the silicon oxynitride film in an inert or reducing ambient includes annealing the silicon oxynitride film in an inert gas or a mixture of inert gas.

11. The method of forming a gate stack of claim 9 wherein the annealing of the silicon oxynitride film in an oxidizing ambient includes annealing the silicon oxynitride film with oxygen (O₂) or oxygen comprising gas.

12. The method of forming a gate stack of claim 9 wherein the nitrogen incorporated into the dielectric film has a nitrogen concentration equal to or greater than 5%.

13. A method of forming a gate stack comprising:
placing a substrate into a first processing chamber of a cluster tool, the cluster tool having a plurality of processing chambers;
forming a silicon dioxide film on the substrate in the first processing chamber;
without breaking vacuum, transferring the substrate from the first processing chamber into a second processing chamber capable of performing a plasma nitridation process;
introducing a nitrogen reaction gas into the second processing chamber, to perform the plasma nitridation process while maintaining pressure of the second processing chamber at about or less than about 10 Torr to form a silicon oxynitride film;
without breaking vacuum, transferring the substrate from the second processing chamber to a third processing chamber capable of performing a rapid thermal reaction process to perform a first post plasma nitridation annealing on the silicon oxynitride in an inert or reducing ambient and to perform a second post plasma nitridation annealing on the silicon oxynitride in an oxidizing ambient; and
without breaking vacuum, transferring the substrate from the third processing chamber to a fourth processing chamber capable of performing a deposition process to form a gate electrode on the silicon oxynitride.

14. The method of claim 13 wherein the gate electrode is one of a polysilicon film or an amorphous silicon film.

15. The method of claim 13 further comprising:
continuing the plasma nitridation process for a sufficient amount of time for nitrogen to be incorporated into the silicon dioxide film to a nitrogen concentration of about or more than 5%.

16. The method of claim 13 wherein the first post plasma nitridation annealing occurs at a temperature between about 700° C. and about 1100° C.

17. The method of claim 13 wherein the second post plasma nitridation annealing occurs at a temperature between about 900° C. and 1100° C.

18. The method of forming a gate stack of claim 13 wherein the nitrogen incorporated into the dielectric film forms a nitrogen concentration peak that occurs at the top surface of the dielectric film.

19. The method of forming a dielectric film of claim 13 wherein the annealing of the silicon oxynitride film in an inert or reducing ambient includes annealing the silicon oxynitride film in an inert gas or a mixture of inert gas.

20. The method of claim 13 wherein the annealing of the silicon oxynitride film in an oxidizing ambient includes annealing the silicon oxynitride film with oxygen (02) or oxygen comprising gas.

21. The method of forming a dielectric film of claim 13 wherein the plasma nitridation process includes decoupled plasma nitridation.

22. A method of treating a dielectric film comprising:
exposing the dielectric film to plasma nitridation to incorporate nitrogen into the dielectric film.
subjecting the dielectric film to a first post plasma nitridation annealing wherein a reducing or inert ambient is used, the first post plasma nitridation annealing densifier nitrogen in the dielectric film; and
subjecting the dielectric film to a second post plasma nitration annealing wherein an oxidizing ambient is used.

23. The method of treating a dielectric film of claim 19 wherein the plasma nitridation is decoupled plasma nitridation.

24. The method of treating a dielectric film of claim 19 wherein the dielectric film is silicon dioxide (SiO₂).

25. The method of treating a dielectric film of claim 19 wherein after the nitrogen is incorporated, a silicon oxinytride is formed.

26. The method of treating a dielectric film of claim 19 wherein the first post plasma nitridation annealing occurs at a temperature ranging between about 700° C. and 1100° C.

27. The method of treating a dielectric film of claim 19 wherein the second post plasma nitridation annealing occurs at a temperature ranging between about 900° C. and 1100° C.

28. The method of treating a dielectric film of claim 19 wherein the reducing or inert ambient includes using an inert gas to create the reducing or inert ambient.

29. The method of treating a dielectric film of claim 19 wherein the oxidizing ambient includes using oxygen comprising gas or gas mixture to create the oxidizing ambient.

30. The method of treating a dielectric film of claim 19 wherein the nitrogen incorporated into the dielectric film has a nitrogen concentration equal to or greater than 5%.
